(19) United States
(12) Patent Application Publication
(10) Pub. No.: US 2022/0138616 A1
(43) Pub. Date: May 5, 2022

(54) SCALABLE DISCOVERY OF LEADERS FROM DYNAMIC COMBINATORIAL SEARCH SPACE USING INCREMENTAL PIPELINE GROWTH APPROACH

(71) Applicant: INTERNATIONAL BUSINESS MACHINES CORPORATION, ARMONK, NY (US)

(72) Inventors: Dhavalkumar C. Patel, White Plains, NY (US); Shrey Shrivastava, White Plains, NY (US); Jayant R. Kalagnanam, Briarcliff Manor, NY (US); Stuart Siegel, Millburn, NJ (US); Wesley M. Gifford, Ridgefield, CT (US); Chandrasekhara K. Reddy, Kinnelon, NJ (US)

(21) Appl. No.: 17/086,277

(22) Filed: Oct. 30, 2020

(51) Int. Cl. G06N 20/00; G06F 16/28

(52) U.S. Cl. CPC G06N 20/00; G06F 16/288

(57) ABSTRACT

A computer implemented method includes generating a pipeline graph having a plurality of layers, each of the plurality of layers having one or more machine learning components for performing a predictive modeling task. A plurality of pipelines are operated through the pipeline graph on a training dataset to determine a respective plurality of results. Each of the plurality of pipelines are distinct paths through selected ones of the one or more machine learning components at each of the plurality of layers. The plurality of results are compared to known results based on a user-defined metric to output one or more leader pipelines.

### BACKGROUND

### Technical Field

The present disclosure generally relates to artificial intelligence and machine learning systems, and more particularly, to methods and systems for scalable discovery of the predictive modeling pipelines (hereafter referred to as “leaders”) within a dynamic combinatorial search space using a heuristic-based method.

### Description of the Related Art

The term “predictive modeling” in the field of data science refers to the process of analysis to discover the best data transformations and modeling forms for ultimately drawing accurate and meaningful inference from new realizations of data. Predictive modeling is of fundamental interest to researchers in machine learning, pattern recognition, databases, statistics, artificial intelligence, knowledge acquisition for expert systems and data visualization.

In the machine learning community, researchers or data scientists build a pipeline to define a series of steps to be performed on an input dataset for building a model.

### SUMMARY

According to various embodiments, a computing device, a non-transitory computer readable storage medium, and a method are provided for permitting data scientists to proficiently explore multiple pipelines to improve upon the efficiency of a model exploration task on a given dataset.

In one embodiment, a computer implemented method includes generating alternative pipeline graphs having a plurality of layers, each of the plurality of layers or steps having one or more machine learning components for performing a predictive modeling task. The method further entails the inclusion of the pipelines within a pipeline graph to determine a respective plurality of results for a given training dataset. The method further includes comparing the plurality of results to known results based on a user-defined metric to output one or more leader pipelines, where the leaders refers to those predictive models with the best performance for some performance metric.

In some embodiments, the pipeline graph is generated from one or more default pipeline graphs for the predictive modeling task.

In some embodiments, the one or more machine learning components include a no-operation component, where the training dataset passes without operation when the pipeline includes the no-operation component.

In some embodiments, the method further comprises applying a set of hyperparameters to one or more of the selected ones of the one or more machine learning components at each of the plurality of layers.

In some embodiments, the method further comprises applying a hyperparameter optimization scheme to reduce a size of a hyperparameter search space.

In some embodiments, the method further comprises initially operating the one or more machine learning components at a last layer of the pipeline graph on the training dataset using a default hyperparameter for each of the one or more machine learning components of the last layer.

In some embodiments, the method further comprises selecting a first portion of the one or more machine learning components of the last layer, the first portion being closest to the known result. In some embodiments, the first portion is about one-half of the one or more machine learning components of the last layer.

In some embodiments, the method further comprises initiating a first hyperparameter tuning on the first portion to determine a tuned set of hyperparameters for each of the first portion of the one or more machine learning components and selecting a second portion of the first portion, the second portion having the best performance. In some embodiments, the second portion is about one-half of the machine learning components of the first portion.

In some embodiments, the method further comprises initiating a second hyperparameter tuning on the second portion to determine a second tuned set of hyperparameters for each of the second portion of the one or more machine learning components of the last layer of the pipeline graph.

In some embodiments, the method further comprises adding an additional one of the plurality of layers and identifying a plurality of smaller paths using each of the one or more machine learning components of the additional one of the plurality of layers and each of the second portion. The smaller pipeline paths serve as a filtering mechanism for the full-length paths to provide a computationally fast means of pruning the overall pipeline graph of pathways that would likely not be fruitful from a predictive modeling accuracy perspective. The method further includes operating the plurality of smaller pipeline paths on the training dataset with the default hyperparameters for each of the two machine learning components of each of the plurality of smaller pipeline paths and selecting a first portion of the smaller pipeline paths, the first portion being closest to the known result. The method further includes initiating a third hyperparameter tuning on the first portion of the smaller pipeline paths to determine a tuned set of hyperparameters for each of the machine learning components of the first portion of the smaller pipeline paths.

According to various embodiments, a computer implemented method includes generating a pipeline graph having a plurality of layers, each of the plurality of layers having one or more machine learning components for performing a predictive modeling task and operating each of the one or more machine learning components at a last layer of the pipeline graph on a training dataset using a default hyperparameter for each of the one or more machine learning components of the last layer. The method further includes selecting a first portion of the one or more machine learning components of the last layer, the first portion having the best performance of the predictive modeling task and initiating a first hyperparameter tuning on the first portion to determine a tuned set of hyperparameters for each of the first portion of the one or more machine learning components. The method further includes selecting a second portion of the first portion, the second portion having the best performance of the predictive modeling task when the tuned set of hyperparameters are applied and initiating a second hyperparameter tuning on the second portion to determine a second tuned set of hyperparameters for each of the second portion of the one or more machine learning components of the last layer of the pipeline graph. The method further includes adding an additional one of the plurality of layers and identifying a plurality of extended pipeline paths using each of the one or more machine learning components of the additional one of the plurality of layers and each of the second portion. The method further includes operating the plurality of extended pipeline paths on the training dataset with the default hyperparameters for each of the one or more machine learning components of the additional one of the plurality of layers. The method further includes selecting a third portion of the extended pipeline paths, the third portion being closest to the known result and initiating a third hyperparameter tuning on the third portion of the extended pipeline paths to determine a second tuned set of hyperparameters for each of the machine learning components of the additional one of the plurality of layers.

According to various embodiments, a non-transitory computer readable storage medium tangibly embodying a computer readable program code having computer readable instructions that, when executed, causes a computer device to carry out a method of improving computing efficiency of a computing device operating a pipeline execution engine. The method includes generating a pipeline graph having a plurality of layers, each of the plurality of layers having one or more machine learning components for performing a predictive modeling task and operating a plurality of pipelines through the pipeline graph on a training dataset to determine a respective plurality of results, wherein each of the plurality of pipelines are distinct paths through selected ones of the one or more machine learning components at each of the plurality of layers. The method further includes comparing the plurality of results to known results based on a user-defined metric to output one or more leader pipelines.

By virtue of the concepts discussed herein, a system and method are provided that improves upon the approaches currently used in machine learning model exploration. These concepts can assure scalability and efficiency of machine learning model exploration while providing a predetermined set of parameters for non-experts that may be fully modified as desired by more advanced users.

These and other features will become apparent from the following detailed description of illustrative embodiments thereof, which is to be read in connection with the accompanying drawings.

### BRIEF DESCRIPTION OF THE DRAWINGS

The drawings are of illustrative embodiments. They do not illustrate all embodiments. Other embodiments may be used in addition or instead. Details that may be apparent or unnecessary may be omitted to save space or for more effective illustration. Some embodiments may be practiced with additional components or steps and/or without all the components or steps that are illustrated. When the same numeral appears in different drawings, it refers to the same or like components or steps.

FIG. 1 is a schematic representation of a sample pipeline for a regression function that can be identified via methods and systems according to an embodiment of the present disclosure.

FIG. 2 is a schematic representation of the use of a pipeline graph for pipeline leader generation, consistent with an illustrative embodiment.

FIG. 3 is a graph illustrating details of a regression pipeline graph, consistent with an illustrative embodiment.

FIG. 4 is a graph illustrating the execution of the regression pipeline graph of FIG. 3 on various platforms, consistent with an illustrative embodiment.

FIG. 5 is a schematic representation of acts performed by a staged distributed optimizer, consistent with an illustrative embodiment.

FIG. 6 is a flow chart describing a method consistent with an illustrative embodiment.

FIG. 7 is a functional block diagram illustration of a computer hardware platform that can be used to implement a particularly configured computing device that can host a system for machine learning model exploration using a pipeline graph, consistent with an illustrative embodiment.

### DETAILED DESCRIPTION

In the following detailed description, numerous specific details are set forth by way of examples to provide a thorough understanding of the relevant teachings. However, it should be apparent that the present teachings may be practiced without such details. In other instances, well-known methods, procedures, components, and/or circuitry have been described at a relatively high-level, without detail, to avoid unnecessarily obscuring aspects of the present teachings.

Unless specifically stated otherwise, and as may be apparent from the following description and claims, it should be appreciated that throughout the specification descriptions utilizing terms such as “processing,” “computing,” “calculating,” “determining,” or the like, refer to the action and/or processes of a computer or computing system, or similar electronic computing device, that manipulate and/or transform data represented as physical, such as electronic, quantities within the computing system's registers and/or memories into other data similarly represented as physical quantities within the computing system's memories, registers or other such information storage, transmission or display devices.

As discussed in greater detail below, the present disclosure generally relates to a system for machine learning model exploration using a pipeline graph where a staged distributed optimization can be used for the scalable discovery of leaders. The systems and computerized methods provide a technical improvement in the efficiency, scalability and adaptability for generating machine learning pipelines for a given task using a given dataset, while allowing for end user control of parameter specifications, execution environment, and model metrics, such as time constraints, memory constraints, diversity of results, accuracy, precision, and the like.

Reference now is made in detail to the details illustrated in the accompanying drawings and discussed below.

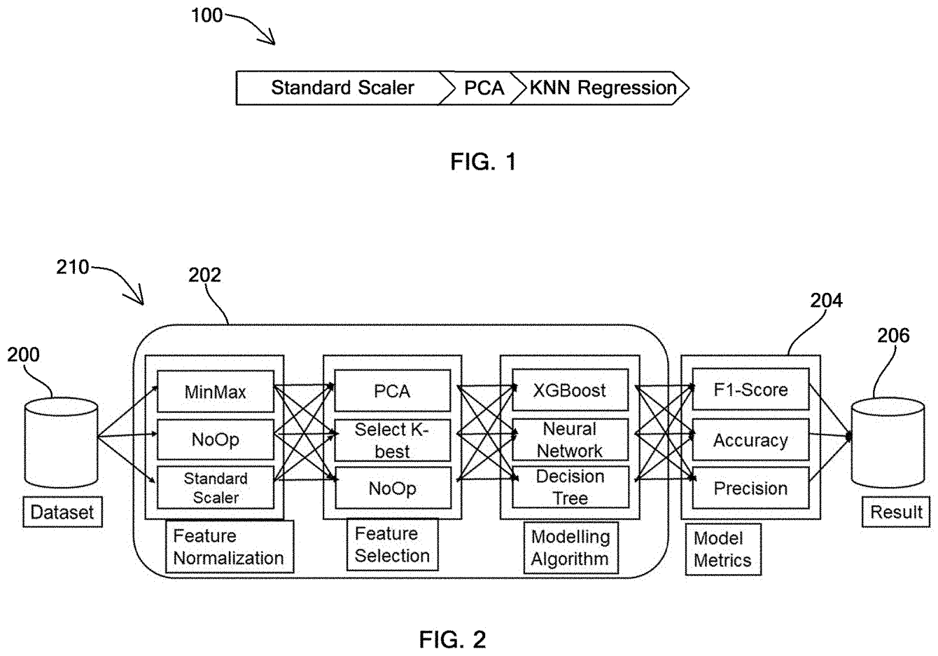

Referring to FIG. 1, a sample pipeline 100 is shown. A machine learning pipeline refers to a workflow, including a series of transformers and a final estimators. A machine learning pipeline, such as sample pipeline 100, is a component in many industrial application systems for fault detection, anomaly prediction, and the like. There are many known estimators and transformers in machine learning. It can be time consuming and it can require substantial computing resources to determine leaders for a given modeling task. As used herein, the term “leaders” refers to a machine learning pipeline, such as sample pipeline 100, that provides an optimal selection of transformers and estimators as well as an optimal pipeline length with tuned hyper-parameters to predict an outcome for a given modeling task. Systems and methods for the generation of such leaders are described in greater detail below. As used herein, an “optimal” pipeline length can refer to achieving the best score for some user-defined metric, such as accuracy for example.

To make the model exploration task easier, the concept of a “Pipeline Graph” is established. A pipeline graph defines the nature of and ordering of the operations to perform when exploring predictive models for tasks such as classification, regression, or clustering. A pipeline graph, denoted as G(V, E), is a directed acyclic rooted graph (DAG) with a set V of vertices and a set E of edges. Each vertex vᵢ∈V represents an operation to be performed on the input data, and an edge eᵢ∈E represents the ordering of operations between vertices. A pipeline graph can prescribe a series of steps, such as feature scaling, feature transformation, feature selection, model learning, and the like, to find the best solution for given training data instance.

Referring to FIG. 2, an exemplary system 210 for machine learning model exploration includes a dataset 200 on which a pipeline graph 202 operates. The dataset 200 may be a training dataset, where task results are known and each path through the pipeline graph 202 can provide a prediction that can be compared to a known prediction to determine pipeline leaders. Each path through the pipeline graph 202 may be operated on by one or more model metrics 204 to provide a result 206. The result can include one or more pipelines (leaders), such as sample pipeline 100 (see FIG. 1) that optimizes the result (that is, comes closest to the known result) based on a selected one or more of the model metrics 204.

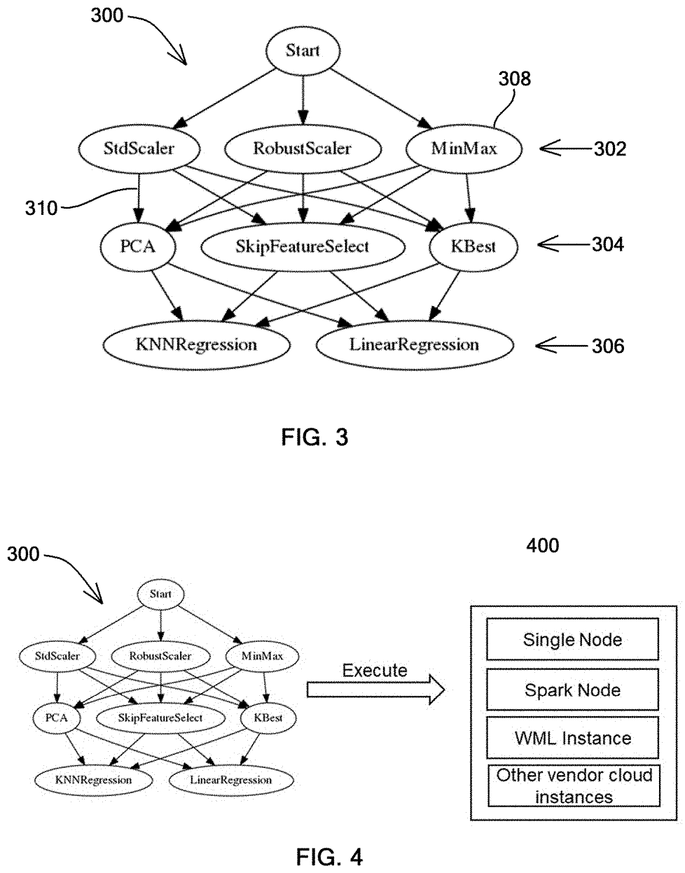

In FIG. 3, a pipeline graph 300 for a regression task is provided for better understanding. In the pipeline graph 300, each layer 302, 304, 306 comprises multiple options. A path through the pipeline graph 300 can represent a single machine learning pipeline. The end user is interested in identifying the best path (or top-k number of paths) for a given dataset.

The pipeline graph 300 can be set up by the user to include three stages: i) feature scaling, ii) feature selection, and iii) classification. The feature scaling stage, at layer 302, includes three popular methods MinMaxScaler, RobustScaler, StandardScaler and may further include option to exclude the stage (i.e., “noop” meaning no operation). The next stage, at layer 304, is feature selection using PCA or SelectKBest or SkipFeatureSelect. The final stage, at layer 306 includes regression models to explore.

The pipeline graph 300 includes multiple end-to-end machine learning/artificial intelligence pipelines that provide prescriptions for how input data are to be manipulated and ultimately modeled. The prescriptions includes scaling operations, explored models, the definition of hyperparameter (HP) grids and how they are explored (e.g., random-search, grid-search, and the like).

Each vertex vᵢ in G is referred to as a pipeline node 308 and edge 310 represents the ordering of operations between pipeline nodes 308. Pipeline nodes 308 include a name and/or the operation it performs and a reference to the python object containing the functional implementation. It is represented by a tuple vᵢ=(nameᵢ, objectᵢ). For example, tuple (“pca”, PCA( )) represents a pipeline node, with name “pca”, that performs principle component analysis. The nodes in FIG. 3 are labeled with the node name.

The name given to each node 308 in the pipeline graph 300 should be unique. The node name is a tag that enables a user to supply additional information that can be used to control the behavior of the node. One such example is to specify a parameter value prefixed by the node name adopting the convention used in scikit-learn. For example, “gradientboostingregressor_n_estimators” would associate with the parameter “n_estimators” of the scikit-learn object GradientBoostingRegressor. As described in greater detail below, by adopting such a standard convention, hyperparameter grids can be developed for parameter optimization.

The operation performed by a pipeline node 308 is either of two types—Transform(_.transform) or Estimate(_.fit). An Estimate operation is typically applied to a collection of data items to produce a trained model. A Transform operation uses a trained model on individual data items or on a collection of items to produce a new data item.

A pipeline path of a pipeline graph G(V, E), denoted as Pi={vᵣₒₒₜ→v₁→ . . . →vⱼ→ . . . →vₖ}, is a directed path of nodes vⱼ∈V that starts from the root node vᵣₒₒₜ and ends at leaf node vₖ. Briefly, a pipeline path chains together artificial intelligence/machine learning-related operations common to the overall task of building predictive models. For example, the left most pipeline path of the pipeline graph in FIG. 3 is given as:

P₁={start→Standard Scaler→PCA→KNN Regression}

There are 18 total pipeline paths to explore in FIG. 3. This is calculated as follows: 3 (feature scalers on the first level 302)×3 (feature selectors on the second level 304)×2 (regression models on the third level 306).

As illustrated in FIG. 4, the pipeline graph 300 can be executed in various runtimes 400, such as a single node, a spark cluster, a Watson machine learning (WML) instance, other vendor cloud instances, or the like.

The pipeline graph 300, while illustrated for use in a regression predictive model, is a universal, general purpose exploration mechanism for any artificial intelligence capability. The pipeline graph 300 can explore many paths to find the best one and can be customizable with respect to many parameters, such as number of layers, which models are used from a selection of available machine learning models, and the ability to utilize specialized, user-produced models. With the pipeline graph 300 used for machine learning model exploration, individual pipelines can be executed in parallel to generate optimal pipelines.

The table below illustrates example modelling tasks in which the pipeline graph concept can be applied to generate optimized pipelines for predictive models for a given task. The table illustrates typical number of layers and nodes used for various modelling tasks. The table further illustrates the number of possible pipelines that may be explored to determine the best pipelines based on the model metrics 204 (see FIG. 2) provided by the user.

| Modelling Task | Layers | Nodes | Pipelines |
|---|---|---|---|
| Regression | 5 | 130+ | ~150,000 |
| Classification | 5 | 140+ | ~160,000 |
| Imbalance Classification | 3 | 40+ | ~20,000 |
| Time Series Prediction | 3 | 30+ | ~200 |
| Imputations | 2 | 10+ | ~40 |
| Anomaly Detection | 2 | 50+ | ~120 |

While the pipeline graph provides the aforementioned flexibility to add a sequence of machine learning algorithms of a user's choice, it also includes another capability. Many machine learning algorithms come with a set of parameters, such as the choice of the kernel function in support vector machine (SVM), the depth of the tree in decision tree classification, the number of projected dimensions in principle component analysis (PCA) transformation, and the like. Such algorithm specific parameters are referred as “hyperparameters”.

In a pipeline graph design, the set of hyperparameters associated with a pipeline node (v) are represented by H(v). Each hyperparameter ρ∈H(v) is further associated with a set of values V(ρ), for example:

[symbol]

v,ρ [symbol] →V(ρ)∀ρ∈H(v)

For example, for the PCA algorithm, a user may be interested in setting the parameter for the number of components to value in the set [3, 5, 7, 10].

[symbol]

v=PCA,ρ=n_components [symbol] →[3,5,7,10]

This functionality is achieved in the system, according to aspects of the present disclosure, by making the hyperparameter an attribute of the pipeline node and separately defining mappings which associate an algorithm and hyperparameter to a set of values. Note that while V(φ is referred to as a set of values, it may be a discrete set of values or continuous values sampled from a range or a particular distribution.

Typically, machine learning algorithms have more than one hyperparameter, so users wish to try combinations of parameters for different algorithms within a pipeline path. To support this concept, methods according to aspects of the present disclosure define “hyperparameter grids” for many common machine learning tasks grouped by function (e.g., a regression grid, a classification grid, and the like). Coarse and fine grids can be defined which differ in size and thus computational burden they impose.

An objective of a pipeline execution engine 820 (see FIG. 8) is to discover the best model (i.e., best pipeline path) for an input dataset D. Since the computational workload originating from the execution of a pipeline graph is very high, aspects of the present disclosure employ two complementary strategies for speeding up pipeline execution: 1) parallel and, optionally, distributed execution with an option for time-bounded execution of pipeline paths, and 2) an optimization-based hyperparameter tuning approach, where, in some embodiments as discussed below, an early phase of hyperparameter tuning can perform, for example, random search and the knowledge of this exploration can be fed into a more sophisticated optimizer, such as RBGOpt, for example.

A task is a discrete section of computational work. For example, an execution of a single pipeline path is treated as one task. One strategy is to run multiple tasks (i.e., pipeline paths) in a parallel (preferably distributed) and time-bounded manner. In one embodiment, tasks can be created at multiple levels of granularity to achieve different levels of parallelism.

Path-level parallelism involves running each pipeline path in parallel. In this setting, the evaluation is parallelized across paths, where each task contains a distinct path and is responsible for evaluating the path for a number of parameter choices. This option is referred to as a “path learning”.

Parameter-level parallelism involves running each pipeline path for different hyperparameter combinations in parallel. In this setting, the evaluation is parallelized across the parameters so that each task gets the same path, but a different point in the hyperparameter space. This option is referred to as “param_learning”.

The pipeline execution engine 720 can support parameter and path-level parallelism. The latter is used by default unless a user specifies a hyperparameter grid or when a particular hyperparameter optimization strategy only supports sequential operation (such as those that estimate gradients within the search routine).

Another strategy for speeding up pipeline execution is to use an optimization technique to reduce the size of the hyperparameter search space (compared to, for example, fully enumerated grid search) for each pipeline path. Aspects of the present disclosure can use various known optimization schemes. For example, the pipeline execution engine 720 can support six different optimization schemes: Complete search (compS), Random search (randS), Evolutionary search (evolS), Hyperband search (hbandS), Bayesian-optimization search (bayesS, and RBFOpt search (rbfOptS). A user can select one of the optimizer listed above for discovering the best combination of hyperparameter values and pipeline path. In some embodiments, the selection of the optimizer can be automated by the system.

The capability of the pipeline execution engine 720 can be extended to support automated learning. This autolearning functionality can be referred to as DAG-AI. First, an end user prepares a deep pipeline graph for a given machine learning task. For an entry level data scientist, the system can include prebuilt pipeline graphs for various tasks, such as classification, regression, imbalanced learning, and the like. For example, the pre-built classification graph has a depth of 5 layers, 130+ nodes, ˜160,000 paths, and a hyper-parameter grid with ˜150 entries. The output of the process on a pipeline graph is a best performing pipeline path with a parameter configuration for a given dataset. However, the best performing pipeline path may not include all the nodes along the paths in the graph. In other words, the method explores variable length pipeline paths from a given pipeline graph.

An example solution designed to implement a DAG-AI system aims to discover the best pipeline path with its parameter as early as possible. Discovering a reasonable best solution as early as possible eliminates the need of running experiments for longer duration, thereby conserving valuable computational resources. The idea is to execute a pipeline-graph iteratively over multiple rounds and progressively generate the results at the end of each round. The results generated at the end of the current round is available to the user for quick inspection, as well as, used in subsequent iteration to prune the search space.

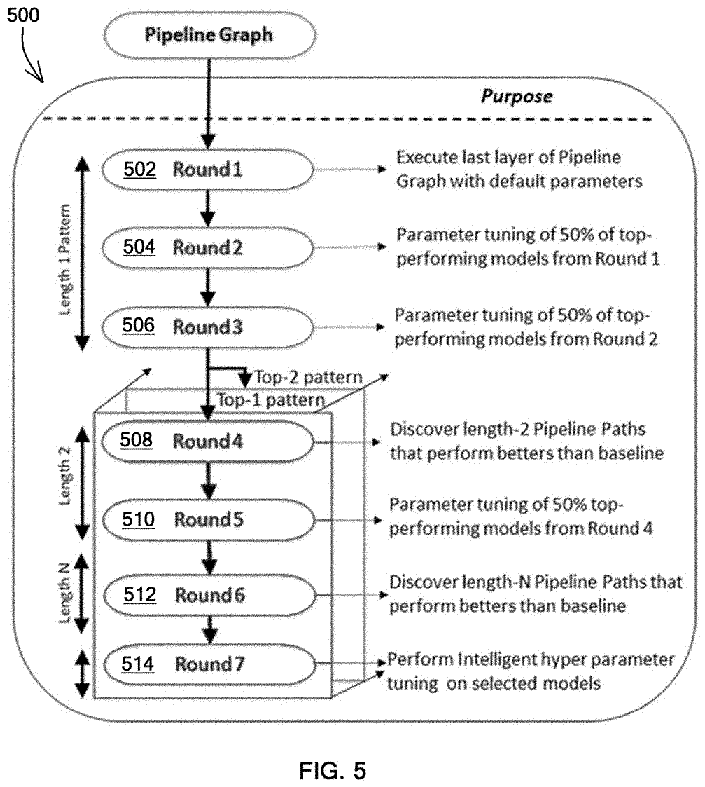

FIG. 5 outlines a method 500 for DAG-AI execution spread over seven rounds. In the first round 502, only the last layer of the pipeline graph (such as layer 306 of the pipeline graph 300 of FIG. 3) is executed. The execution is limited to the default parameters and does not involve any hyperparameter tuning. Note that, the last layer of the pipeline graph comprises machine learning models, such as an estimator or decision maker. The execution can use spark, celery or a cloud engine for processing speed-up, as applicable. The model performance obtained at the end of the first round 502 act as a baseline for subsequent operation. In one embodiment, about 50% of the top-performing models can be selected to become a candidate for the second round 504. This amount may vary but is typically about one-half to significantly reduce the number of models to move into later steps of the process. The first round result is also available to the user.

In the second round 504, a random search based hyperparameter tuning is initiated on the models that are selected in previous round (first round 502). A randomized hyperparameter tuning is a highly parallel activity. The number of parameters to be tried out for each model in the current round is adjustable but is typically kept to a small value, such as 10. In the early stage of execution, the exploration search space can be controlled. In this round, nearly 10+ different models can be run with 10 different randomly generated parameter values. Out of 10+ models, nearly 50% of the top-performing models can be selected to become a candidate for the third round 506.

In the third round 506, a random search based hyperparameter tuning is initiated on the models that are selected in previous round (second round 504). Compared to the previous round, the number of parameters to be tried out for each model in this round is greater that the number of parameters in the second round 504 and is adjustable. In some embodiments, nearly 5+ different models are run with 30 different parameter values in the third round 506. In should be noted that some models do not have many parameters to be tuned.

After successful completion of first three rounds, length-1 pipeline paths (along with the parameters) are identified that perform better than the other pipeline paths. To reduce exploration of a huge search space, embodiments of the present disclosure can select k (≤5) top-performing models here-after and derive k pipeline-graphs, one for each top-performing model. Each of these new pipeline-graph's last layer has only one node. A new pipeline graph can be denoted for the kth top-performing models as PGₖ. For example, assuming that a “KNN Regression” is a top performing algorithm, then the resultant pipeline graph only has one node in the last layer.

In rounds 4 and 5, one focus is on discovering smaller pipeline paths for each top-performing models. Given a pipeline graph Gₖ for a kth top-performing model, Gₖ can be decomposed into multiple pipeline graphs of depth-2, for example. In should be noted that, the last layer in each decomposed graph is same, that is, the kth top-performing model. Next, each decomposed graph can be processed in two stages (i.e., a fourth round 508 and a fifth round 510) to discover a smaller pipeline path that perform better than the pipeline path from which it got enlarged. The fourth round 508 is similar to the first round 502, where pipelines with default parameters are tried, whereas, the fifth round 510 is similar to the second round 504, where randomized hyperparameter tuning is conducted on the top performing paths outputted by the fourth round 508. After the fourth and fifth rounds 508, 510, it is known which nodes, other than nodes from previous stages, also help to improve the performance. In the sixth round 512, these nodes can be used to grow a longer length pipeline path. The process can be repeated to extend the length of the pipeline, incrementally, as needed or desired to improve the performance of the pipeline. Use of the process 500 can reduce the search space by about 90 percent, thus increasing processing speed and reducing required processing resources.

Up until the sixth round 502, highly parallelized randomized search operations can be used. In the seventh round 514, intelligent search mechanisms can be applied for promising pipeline paths that have been discovered. In particular, given a path, other hyperparameter optimization schemes, such as evolS, hbandS, bayesS, and rbfOptS, can be applied on each path to discover hyperparameter tuning that can help to improve the performance. Instead of applying the intelligent method on each and every pipeline path, this method is applied on top-performing pipeline paths to improve the execution time.

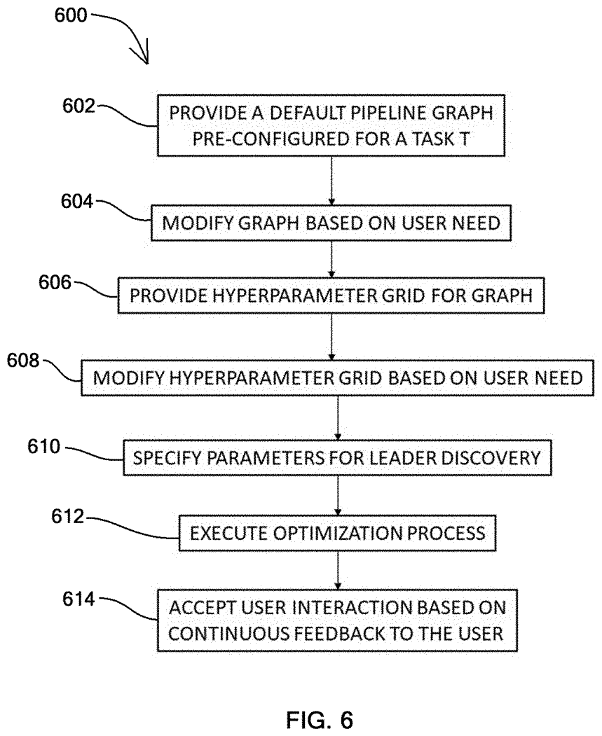

With the foregoing overview of the example system 210 (see FIG. 2) for machine learning model exploration, it may be helpful now to consider a high-level discussion of an example process. To that end, FIG. 6 presents an illustrative process related to providing machine learning pipelines based on a task-specific pipeline graph. Process 600 is illustrated as a collection of blocks, in a logical flowchart, which represents a sequence of operations that can be implemented in hardware, software, or a combination thereof. In the context of software, the blocks represent computer-executable instructions that, when executed by one or more processors, perform the recited operations. Generally, computer-executable instructions may include routines, programs, objects, components, data structures, and the like that perform functions or implement abstract data types. In each process, the order in which the operations are described is not intended to be construed as a limitation, and any number of the described blocks can be combined in any order and/or performed in parallel to implement the process. For discussion purposes, the process 600 is described with reference to the system 210 of FIG. 2.

Referring to FIG. 6, the process 600 for providing machine learning pipelines based on a task-specific pipeline graph is illustrated consistent with an exemplary embodiment. A user, with dataset D and a modeling task T can utilize the process 600 to generate one or more pipelines that can achieve a user-defined goal, such as precision, accuracy, F-1 score, or the like. The process can include an act 602 where the system offers a default pipeline graph G with pre-configured steps based on task T. The system can store default pipeline graphs for each task, where, when the user identifies such a task, the associated default pipeline graph is provided for the user. Optionally, at act 604, a user can modify graph G based on need. The size of graph G can vary based on task and end user need. In some embodiments, more than one default pipeline graph can be available for each task, where each of these default pipeline graphs may be designed to address specific user needs, such as minimizing computational resources, minimizing run time, increasing accuracy, or the like.

At act 606, the system can offer a suitable hyperparameter grid for the graph G. At act 608, a user may optionally modify the hyperparameter grid based on need.

At act 610, the end user can specify parameters for leader discovery. For example, the user can define how many leaders are to be discovered and their diversity (e.g., share the model but use different data processing steps). The user can define how much time and the maximum memory that is given to each leader for training. The user can set evaluation metrics (e.g., the model metrics 204 of FIG. 2) for defining the quality of the leaders. The user can also select an execution environment.

At act 612, the system can execute an optimization process for discovering pipelines. The optimization process can include an iterative search over the pipeline graph, can use incremental pipeline pattern growth, and can use a distributed execution which can result in improvement in leader discovery as time progresses.

At act 614, the user can interact with the system throughout the process, based on continuous feedback provided by the system. The user may perform various tasks, such as increasing time or memory (if many pipelines fail in an early stage, for example), remove certain components that result in poor performance or are a bottleneck, perform an iterative refinement in case of execution restart, suggest models that are top performers in early stages, print results summary of common components of leaders, and the like.

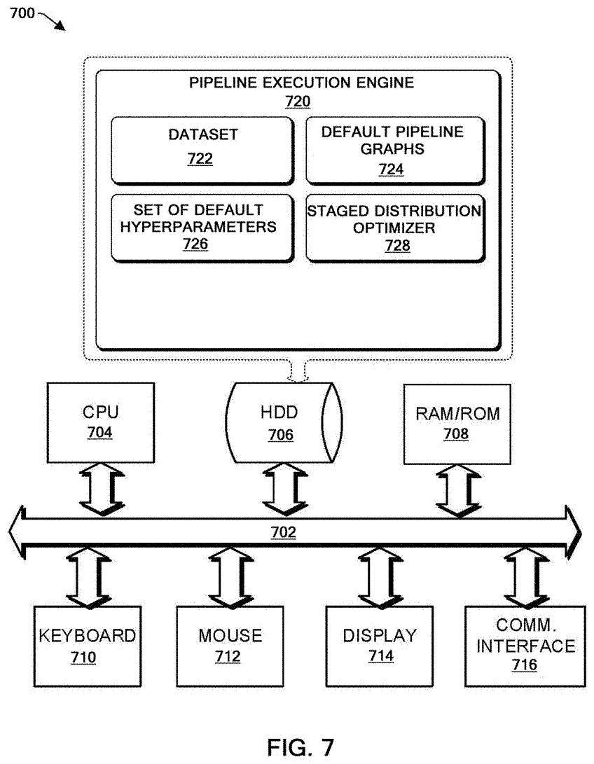

FIG. 7 provides a functional block diagram illustration of a computer hardware platform 700 that can be used to implement a particularly configured computing device that can host a pipeline execution engine 720. The pipeline execution engine 720 can provide machine learning model exploration, as discussed in detail above. The pipeline execution engine 720 can include a dataset 722, a set of default pipeline graphs 724 for each task, a set of default hyperparameters 726 for each task, and a staged distributed optimizer 728. In particular, FIG. 7 illustrates a network or host computer platform 700, as may be used to implement an appropriately configured pipeline execution engine 720.

The computer platform 700 may include a central processing unit (CPU) 704, a hard disk drive (HDD) 706, random access memory (RAM) and/or read only memory (ROM) 708, a keyboard 710, a mouse 712, a display 714, and a communication interface 716, which are connected to a system bus 702.

In one embodiment, the HDD 706, has capabilities that include storing a program that can execute various processes, such as the pipeline execution engine 720, in a manner described herein.

### CONCLUSION

The descriptions of the various embodiments of the present teachings have been presented for purposes of illustration but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

While the foregoing has described what are considered to be the best state and/or other examples, it is understood that various modifications may be made therein and that the subject matter disclosed herein may be implemented in various forms and examples, and that the teachings may be applied in numerous applications, only some of which have been described herein. It is intended by the following claims to claim any and all applications, modifications and variations that fall within the true scope of the present teachings.

The components, steps, features, objects, benefits and advantages that have been discussed herein are merely illustrative. None of them, nor the discussions relating to them, are intended to limit the scope of protection. While various advantages have been discussed herein, it will be understood that not all embodiments necessarily include all advantages. Unless otherwise stated, all measurements, values, ratings, positions, magnitudes, sizes, and other specifications that are set forth in this specification, including in the claims that follow, are approximate, not exact. They are intended to have a reasonable range that is consistent with the functions to which they relate and with what is customary in the art to which they pertain.

Numerous other embodiments are also contemplated. These include embodiments that have fewer, additional, and/or different components, steps, features, objects, benefits and advantages. These also include embodiments in which the components and/or steps are arranged and/or ordered differently.

Aspects of the present disclosure are described herein with reference to a flowchart illustration and/or block diagram of a method, apparatus (systems), and computer program products according to embodiments of the present disclosure. It will be understood that each block of the flowchart illustrations and/or block diagrams, and combinations of blocks in the flowchart illustrations and/or block diagrams, can be implemented by computer readable program instructions.

These computer readable program instructions may be provided to a processor of an appropriately configured computer, special purpose computer, or other programmable data processing apparatus to produce a machine, such that the instructions, which execute via the processor of the computer or other programmable data processing apparatus, create means for implementing the functions/acts specified in the flowchart and/or block diagram block or blocks. These computer readable program instructions may also be stored in a computer readable storage medium that can direct a computer, a programmable data processing apparatus, and/or other devices to function in a manner, such that the computer readable storage medium having instructions stored therein comprises an article of manufacture including instructions which implement aspects of the function/act specified in the flowchart and/or block diagram block or blocks.

The computer readable program instructions may also be loaded onto a computer, other programmable data processing apparatus, or other device to cause a series of operational steps to be performed on the computer, other programmable apparatus or other device to produce a computer implemented process, such that the instructions which execute on the computer, other programmable apparatus, or other device implement the functions/acts specified in the flowchart and/or block diagram block or blocks.

The call-flow, flowchart, and block diagrams in the figures herein illustrate the architecture, functionality, and operation of possible implementations of systems, methods, and computer program products according to various embodiments of the present disclosure. In this regard, each block in the flowchart or block diagrams may represent a module, segment, or portion of instructions, which comprises one or more executable instructions for implementing the specified logical function(s). In some alternative implementations, the functions noted in the blocks may occur out of the order noted in the Figures. For example, two blocks shown in succession may, in fact, be executed substantially concurrently, or the blocks may sometimes be executed in the reverse order, depending upon the functionality involved. It will also be noted that each block of the block diagrams and/or flowchart illustration, and combinations of blocks in the block diagrams and/or flowchart illustration, can be implemented by special purpose hardware-based systems that perform the specified functions or acts or carry out combinations of special purpose hardware and computer instructions.

While the foregoing has been described in conjunction with exemplary embodiments, it is understood that the term “exemplary” is merely meant as an example, rather than the best or optimal. Except as stated immediately above, nothing that has been stated or illustrated is intended or should be interpreted to cause a dedication of any component, step, feature, object, benefit, advantage, or equivalent to the public, regardless of whether it is or is not recited in the claims.

It will be understood that the terms and expressions used herein have the ordinary meaning as is accorded to such terms and expressions with respect to their corresponding respective areas of inquiry and study except where specific meanings have otherwise been set forth herein. Relational terms such as first and second and the like may be used solely to distinguish one entity or action from another without necessarily requiring or implying any actual such relationship or order between such entities or actions. The terms “comprises,” “comprising,” or any other variation thereof, are intended to cover a non-exclusive inclusion, such that a process, method, article, or apparatus that comprises a list of elements does not include only those elements but may include other elements not expressly listed or inherent to such process, method, article, or apparatus. An element proceeded by “a” or “an” does not, without further constraints, preclude the existence of additional identical elements in the process, method, article, or apparatus that comprises the element.

The Abstract of the Disclosure is provided to allow the reader to quickly ascertain the nature of the technical disclosure. It is submitted with the understanding that it will not be used to interpret or limit the scope or meaning of the claims. In addition, in the foregoing Detailed Description, it can be seen that various features are grouped together in various embodiments for the purpose of streamlining the disclosure. This method of disclosure is not to be interpreted as reflecting an intention that the claimed embodiments have more features than are expressly recited in each claim. Rather, as the following claims reflect, inventive subject matter lies in less than all features of a single disclosed embodiment. Thus, the following claims are hereby incorporated into the Detailed Description, with each claim standing on its own as a separately claimed subject matter.

What is claimed is:

1. A computer implemented method of improving computational efficiency in identifying one or more leaders for a given modeling task, comprising:
generating a pipeline graph having a plurality of layers, each of the plurality of layers having one or more machine learning components for performing a predictive modeling task;
operating a plurality of pipelines through the pipeline graph on a training dataset to determine a respective plurality of results, wherein each of the plurality of pipelines are distinct paths through selected ones of the one or more machine learning components at each of the plurality of layers;
comparing the plurality of results to known results based on a predetermined metric; and
identifying one or more leader pipelines based on the comparison.

2. The computer implemented method of claim 1, wherein the pipeline graph is generated from one or more default pipeline graphs for the predictive modeling task.

3. The computer implemented method of claim 1, wherein:
the one or more machine learning components include a no-operation component; and
the training dataset passes without operation when the pipeline includes the no-operation component.

4. The computer implemented method of claim 1, further comprising applying a set of hyperparameters to one or more of the selected ones of the one or more machine learning components at each of the plurality of layers.

5. The computer implemented method of claim 4, further comprising reducing a size of a hyperparameter search spacy by applying a hyperparameter optimization scheme.

6. The computer implemented method of claim 1, further comprising initially operating the one or more machine learning components at a last layer of the pipeline graph on the training dataset using a default hyperparameter for each of the one or more machine learning components of the last layer.

7. The computer implemented method of claim 6, further comprising selecting a first portion of the one or more machine learning components of the last layer, the first portion a selection of the one or more machine learning components of the last layer providing leading performance of a predictive model.

8. The computer implemented method of claim 7, wherein the first portion is about one-half of the one or more machine learning components of the last layer.

9. The computer implemented method of claim 7, further comprising initiating a first hyperparameter tuning on the first portion to determine a tuned set of hyperparameters for each of the first portion of the one or more machine learning components and selecting a second portion of the first portion, the second portion providing leading performance of the predictive model.

10. The computer implemented method of claim 9, wherein the second portion is about one-half of the machine learning components of the first portion.

11. The computer implemented method of claim 9, further comprising initiating a second hyperparameter tuning on the second portion to determine a second tuned set of hyperparameters for each of the second portion of the one or more machine learning components of the last layer of the pipeline graph.

12. The computer implemented method of claim 11, wherein the first hyperparameter tuning and the second hyperparameter tuning both use a random search based hyperparameter tuning.

13. The computer implemented method of claim 12, further comprising:
adding an additional one of the plurality of layers;
identifying a plurality of expanded pipeline paths using each of the one or more machine learning components of the additional one of the plurality of layers and each of the second portion;
operating the plurality of expanded pipeline paths on the training dataset with the default hyperparameters for each of the two machine learning components of each of the plurality of expanded pipeline paths;
selecting a first portion of the expanded pipeline paths, the first portion providing leading performance for the predictive model; and
initiating a third hyperparameter tuning on the first portion of the extended pipeline paths to determine a tuned set of hyperparameters for each of the machine learning components of the first portion of the extended pipeline paths.

14. A computer implemented method comprising:
generating a pipeline graph having a plurality of layers, each of the plurality of layers having one or more machine learning components for performing a predictive modeling task;
operating each of the one or more machine learning components at a last layer of the pipeline graph on a training dataset using a default hyperparameter for each of the one or more machine learning components of the last layer;
selecting a first portion of the one or more machine learning components of the last layer, the first portion being closest to a known result of the predictive modeling task;
initiating a first hyperparameter tuning on the first portion to determine a tuned set of hyperparameters for each of the first portion of the one or more machine learning components;
selecting a second portion of the first portion, the second portion being closest to the known result when the tuned set of hyperparameters are applied;
initiating a second hyperparameter tuning on the second portion to determine a second tuned set of hyperparameters for each of the second portion of the one or more machine learning components of the last layer of the pipeline graph;
adding an additional one of the plurality of layers;
identifying a plurality of extended pipeline paths using each of the one or more machine learning components of the additional one of the plurality of layers and each of the second portion;
operating the plurality of extended pipeline paths on the training dataset with the default hyperparameters for each of the one or more machine learning components of the additional one of the plurality of layers;
selecting a third portion of the extended pipeline paths, the third portion being closest to the known result; and
initiating a third hyperparameter tuning on the third portion of the extended pipeline paths to determine a second tuned set of hyperparameters for each of the machine learning components of the additional one of the plurality of layers.

15. The computer implemented method of claim 14, wherein the first hyperparameter tuning and the second hyperparameter tuning both use a random search based hyperparameter tuning.

16. The computer implemented method of claim 14, wherein the first portion is about one-half of the one or more machine learning components of the last layer.

17. A non-transitory computer readable storage medium tangibly embodying a computer readable program code having computer readable instructions that, when executed, causes a computer device to carry out a method of improving computing efficiency of a computing device operating a pipeline execution engine, the method comprising:
generating a pipeline graph having a plurality of layers, each of the plurality of layers having one or more machine learning components for performing a predictive modeling task;
operating a plurality of pipelines through the pipeline graph on a training dataset to determine a respective plurality of results, wherein each of the plurality of pipelines are distinct paths through selected ones of the one or more machine learning components at each of the plurality of layers;
comparing the plurality of results to known results based on a predetermined metric; and
identifying one or more leader pipelines based on the comparison.

18. The non-transitory computer readable storage medium of claim 17, wherein the execution of the code by the processor further configures the computing device to perform an act comprising applying a set of hyperparameters to one or more of the selected ones of the one or more machine learning components at each of the plurality of layers.

19. The non-transitory computer readable storage medium of claim 17, wherein the execution of the code by the processor further configures the computing device to perform acts comprising:
operating each of the one or more machine learning components at a last layer of the pipeline graph on a training dataset using a default hyperparameter for each of the one or more machine learning components of the last layer;
selecting a first portion of the one or more machine learning components of the last layer, the first portion being closest to a known result of the predictive modeling task;
initiating a first hyperparameter tuning on the first portion to determine a tuned set of hyperparameters for each of the first portion of the one or more machine learning components;
selecting a second portion of the first portion, the second portion being closest to the known result when the tuned set of hyperparameters are applied; and
initiating a second hyperparameter tuning on the second portion to determine a second tuned set of hyperparameters for each of the second portion of the one or more machine learning components of the last layer of the pipeline graph.

20. The non-transitory computer readable storage medium of claim 19, wherein the execution of the code by the processor further configures the computing device to perform acts comprising:
adding an additional one of the plurality of layers;
identifying a plurality of extended pipeline paths using each of the one or more machine learning components of the additional one of the plurality of layers and each of the second portion;
operating the plurality of extended pipeline paths on the training dataset with the default hyperparameters for each of the one or more machine learning components of the additional one of the plurality of layers;
selecting a third portion of the extended pipeline paths, the third portion being closest to the known result; and
initiating a third hyperparameter tuning on the third portion of the extended pipeline paths to determine a second tuned set of hyperparameters for each of the machine learning components of the additional one of the plurality of layers.
